(19) United States
(12) Patent Application Publication
(10) Pub. No.: US 2015/0294791 A1
(43) Pub. Date: Oct. 15, 2015

(54) CERAMIC INTERPOSER CAPACITOR

(71) Applicant: QUALCOMM Incorporated, San Diego, CA (US)

(72) Inventors: Kyu-Pyung Hwang, San Diego, CA (US); Hong Bok We, San Diego, CA (US); Young Kyu Song, San Diego, CA (US); Dong Wook Kim, San Diego, CA (US)

(73) Assignee: QUALCOMM Incorporated, San Diego, CA (US)

(21) Appl. No.: 14/252,695

(22) Filed: Apr. 14, 2014

(51) Int. Cl. H01G 4/30; H05K 1/18; H01G 4/005; H05K 1/02; H01L 23/00; H01G 4/12

(52) U.S. Cl. CPC H01G 4/30; H01L 24/32; H01L 24/83; H01G 4/12; H01G 4/005; H05K 1/0231; H05K 1/181; H01L 2224/32265; H01L 2224/83801; H01L 2924/1205; H05K 2201/10015

(57) ABSTRACT

A ceramic capacitor is provided that includes a first capacitor surface, a second opposing capacitor surface, and metal plates perpendicular to the first capacitor surface and second opposing capacitor surface. The metal plates extend from the first capacitor surface to the second opposing capacitor surface. The ceramic capacitor is capable of being interposed between a die and a substrate. A portion of the metal plates are capable of being coupled to conductive pads of the die on the first capacitor surface and to conductive pads of the substrate on the second capacitor surface.

### TECHNICAL FIELD

This application relates to decoupling capacitors, and more particularly to a decoupling capacitor with reduced inductance that may be used in thin semiconductor devices.

### BACKGROUND

A digital circuit such as a microprocessor includes numerous transistors that alternate between dormant and switching states. Such digital circuits thus make abrupt current demands when large numbers of transistors switch states. But power supplies cannot react so quickly, resulting in the voltage on the power supply lead or interconnect to the die including the digital system dipping unacceptably. To smooth the power demands, it is conventional to load the power supply lead to the die with decoupling capacitors. The decoupling capacitors store charge that may be released during times of high power demand so as to stabilize the power supply voltage from the external power supply.

It is conventional to mount decoupling capacitors onto a circuit board but such a mounting location increases the circuit board footprint. Moreover, it is desirable to place the decoupling capacitor as close as possible to the die it services. Mounting the decoupling capacitor further away from the die onto the circuit board undesirably increases the parasitic resistance and inductance. Thus, it is conventional to surface mount decoupling capacitors onto the package substrate for the die, increasing the package substrate footprint. To increase density, it is also conventional to embed capacitors such as decoupling capacitors into the package substrate. The performance of such embedded package substrate (EPS) capacitors and surface-mount technology (SMT) capacitors is limited due to equivalent series inductance (ESL) associated with interconnections. The interconnections provide inherent and unwanted inductance.

FIG. 1 is a cross-sectional view of a prior art semiconductor device 100 showing surface mounted capacitors 102 and EPS capacitors 104. Semiconductor device 100 includes an integrated circuit (IC) or die 110 mounted in “flip-chip” orientation with its terminals or bumps (not shown) facing downward to couple with corresponding terminals or pads (not shown) on the upper surface of a package substrate 120 through solder balls 106.

Package substrate 120 can be a single-layer or multi-layer board, and it can include additional terminals or lands (not shown) on its opposite surface for mating with an additional packaging structure, such as a printed circuit board (not shown), through solder balls 122. Package substrate 120 can form part of a chip package for die 110.

Decoupling capacitors are often used to provide a stable signal or stable supply of power to the IC circuitry. Capacitors are further utilized to dampen power overshoot when an electronic device (e.g., an IC-based processor) is powered up, and to dampen power droop when the device begins using power. For example, a processor that begins performing a calculation may rapidly need more current than can be supplied by the on-chip capacitance. In order to provide such capacitance and to dampen the power droop associated with the increased load, capacitance should be available to respond to the current need within a sufficient amount of time. If insufficient voltage is available to the processor, or if the response time of the capacitance is too slow, the die voltage may collapse.

Capacitors, such as decoupling capacitors and capacitors for dampening power overshoot or droop, are generally placed as close as practical to a die in order to increase the capacitors' effectiveness. Often, the capacitors are surface-mounted to the die side of the package.

To be effective, the inductance of the capacitors needs to be low. Thus, it is desirable to minimize the electrical distance between the capacitors and the die 110, thus reducing the inductance value. This can be achieved by placing the capacitors as electrically close as possible to the die 110.

Still referring to FIG. 1, surface mounted capacitors 102 are mounted around the perimeter of the die 110, and provide capacitance to various points on the die 110 through traces and vias (not shown) and planes in the package substrate 120. Because surface mounted capacitors 102 are mounted around the perimeter of the die 110, the path length between the die 110 and a surface mounted capacitor 102 may result in a relatively high inductance between the die 110 and the surface mounted capacitor 102.

EPS capacitors 104 are embedded in the package substrate 120 below the die 110, and they can generally be placed closer to the die 110 than the surface mounted capacitors 102. However, the package substrate 120 can comprise a complex, extensive infrastructure of conductors, including traces, vias, conductive plates, reference planes, shunts, and the like. In some cases, placement of EPS capacitors 104 within the package substrate 120 would interfere with this infrastructure, so the use of EPS capacitors 104 is not always feasible.

In addition to the inductance issues described above, additional issues are raised by the industry's trend to continuously reduce device sizes and packing densities. Because of this trend, the amount of package real estate available to surface-mounted capacitors and to embedded capacitors is becoming increasingly smaller.

Accordingly, there is a need in the art for capacitors with reduced inductance that can be used in thinner and smaller semiconductor devices.

### SUMMARY

To provide a capacitor with reduced inductance that can be used in thin semiconductor devices, a ceramic capacitor is disclosed that includes vertical metal plates extending from a first capacitor surface to a second opposing capacitor surface. The metal plates are perpendicular to the first and second capacitor surfaces. The vertical metal plates are also embedded in a ceramic material. In various embodiments, the ceramic material includes a high-K ceramic material. In some embodiments, the high-K ceramic material has a dielectric constant of greater than about 1000 to 3000. In some embodiments, the dielectric constant is greater than about 3000. The ceramic capacitor is capable of being interposed between a die and a substrate, and the vertical metal plates of the ceramic capacitor are directly coupled to conductive pads on the die and substrate without the use of interconnections (e.g., solder bumps, copper pillars, etc.). In exemplary embodiments, the conductive pads include ground and power pads. In various embodiments, the vertical metal plates include nickel. In some embodiments, the substrate includes a package substrate such as an organic substrate. Alternatively, the substrate may include a semiconductor substrate (a die).

### BRIEF DESCRIPTION OF THE DRAWINGS

FIG. 1 is a cross-sectional view of a semiconductor device with surface mounted capacitors and EPS capacitors in accordance with the prior art.

FIG. 2A is a cross-sectional view of a semiconductor device with a ceramic capacitor interposed between a die and a substrate in accordance with an embodiment of the present disclosure.

FIG. 2B is a detailed cross-sectional view of the ceramic capacitor in FIG. 2A coupled to pads on the die and substrate.

FIG. 2C is a plan view of the ceramic capacitor in FIG. 2A.

FIG. 3A is a perspective view of sheets used to form a ceramic capacitor.

FIG. 3B is a perspective view of multiple sheets from FIG. 3A after stacking of the sheets.

FIG. 3C is a perspective view of the stacked sheets from FIG. 3B, showing the slicing direction.

FIG. 3D is a perspective view of the stacked sheets from FIG. 3C after the slicing.

FIG. 4 is a flowchart for a method of manufacture for a semiconductor device with a ceramic capacitor in accordance with an embodiment of the disclosure.

FIG. 5 illustrates some example electronic systems incorporating a semiconductor device in accordance with an embodiment of the disclosure.

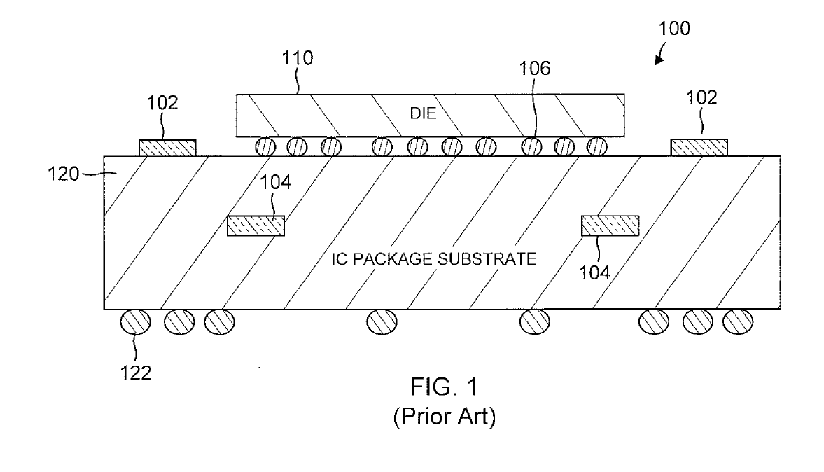

Embodiments of the present disclosure and their advantages are best understood by referring to the detailed description that follows. It should be appreciated that like reference numerals are used to identify like elements illustrated in one or more of the figures. The figures are not to scale.

### DETAILED DESCRIPTION

To meet the need in the art for capacitors with reduced inductance and that can be used in thinner and smaller devices, a ceramic capacitor is disclosed that includes vertical metal plates that are coupled directly to conductive pads on a die and substrate without interconnections (e.g., solder bumps, copper pillars, etc.). The die and substrate each include a plurality of conductive pads on a surface, and the ceramic capacitor is interposed between the die and the substrate. The ceramic capacitor is positioned substantially directly underneath the die in the direction of the substrate. The vertical metal plates of the ceramic capacitor couple with the conductive pads on the die and substrate. In some embodiments, the substrate includes a package substrate such as an organic substrate. Alternatively, the substrate may include a die substrate.

In the following description, specific details are set forth describing some embodiments of the present disclosure. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure.

This description and the accompanying drawings that illustrate inventive aspects and embodiments should not be taken as limiting--the claims define the protected invention. Various mechanical, compositional, structural, and operational changes may be made without departing from the spirit and scope of this description and the claims. In some instances, well-known structures and techniques have not been shown or described in detail in order not to obscure the invention.

Further, this description's terminology is not intended to limit the invention. For example, spatially relative terms--such as “beneath”, “below”, “lower”, “above”, “upper”, “top”, “bottom”, and the like--may be used to describe one element's or feature's relationship to another element or feature as illustrated in the figures. These spatially relative terms are intended to encompass different positions (i.e., locations) and orientations (i.e., rotational placements) of a device in use or operation in addition to the position and orientation shown in the figures. For example, if a device in the figures is turned over, elements described as “below” or “beneath” other elements or features would then be “above” or “over” the other elements or features. Thus, the exemplary term “below” can encompass both positions and orientations of above and below. A device may be otherwise oriented (rotated 90 degrees or at other orientations) and the spatially relative descriptors used herein interpreted accordingly.

### Overview

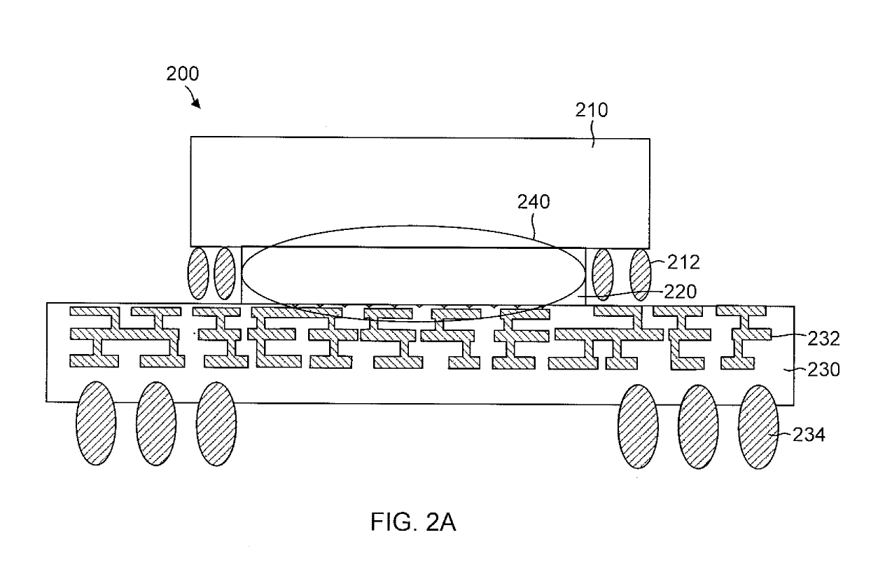

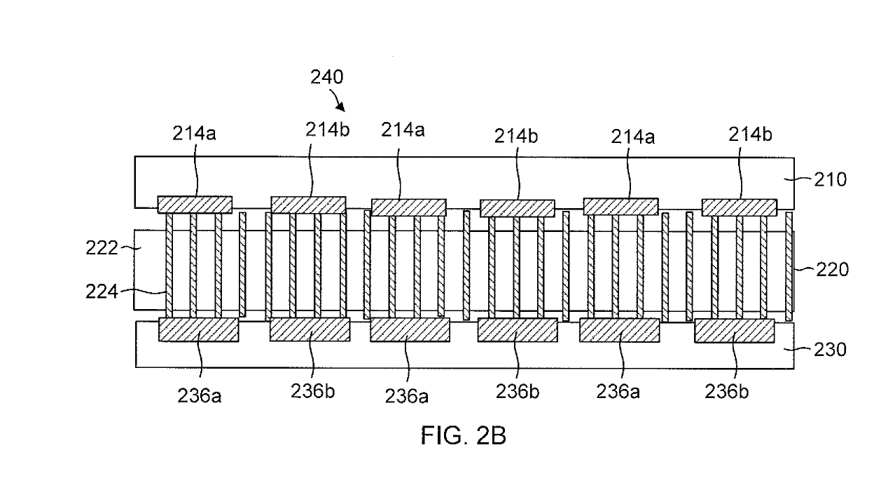

FIG. 2A shows an example semiconductor device 200 comprising a die 210, a ceramic capacitor 220, and a substrate 230. Die 210 can be of any suitable type. In some embodiments, die 210 is a high performance processor. In other embodiments, die 210 could be an application specific integrated circuit (ASIC), custom chip, wireless filter circuit, or any other type of circuit. The subject matter of the present disclosure is not limited to any particular type of die. The die 210 has interconnections 212 to electrically and mechanically couple the die 210 to the substrate 230. In an embodiment, the interconnections 212 include solder bumps.

The substrate 230 may include a package substrate or a die substrate. The substrate 230 may include a wide variety of forms such as an organic substrate or a semiconductor substrate. One can readily appreciate that the present disclosure is independent of the type of substrate.

When the substrate 230 includes a package substrate, the substrate 230 includes conductive layers 232 to carry power, ground, and signals through the substrate 230. In an embodiment, the conductive layers 232 are formed from copper, although other conductive materials such as tin, lead, nickel, gold, palladium, or other materials may be used. Non-conductive material in the substrate 230 may be formed from organic materials, such as epoxy material. The substrate 230 has interconnections 234 to electrically and mechanically couple the substrate 230 to another substrate, such as a printed circuit board (PCB). In some embodiments, the interconnections 234 include solder bumps.

When the substrate 230 includes a die substrate, the substrate 230 may include suitable semiconductor materials such as silicon, germanium, silicon carbide, gallium arsenic, indium arsenide, and indium phosphide. The substrate 230 may include a variety of other features such as p-type doped regions and/or n-type doped regions, isolation features, gate stacks, inter-level dielectric (ILD) layers, and conductive features 232. The substrate 230 has interconnections 234 to electrically and mechanically couple the substrate 230 to another substrate, such as a package substrate. In an embodiment, the interconnections 234 include solder bumps.

Ceramic capacitor 220 is positioned substantially directly underneath the die 210 in the direction of the substrate 230. As shown, the ceramic capacitor 220 is interposed between the die 210 and the substrate 230. The interposed ceramic capacitor 220 prevents warping of the semiconductor device 200 caused by the warping of the substrate 230 due primarily to thermal changes. For example, the ceramic capacitor 220 can help to counteract substrate shrinkage and/or expansion. The structure of the ceramic capacitor 220 is discussed further below.

FIG. 2B shows exemplary details of area 240 in FIG. 2A. Die 210 includes a plurality of conductive pads 214 (pads 214a and 214b are shown) on a surface (e.g., lower surface). The pads 214 can be of any suitable type, geometry, and composition. The pads 214 can be formed of any suitable material, including metals or metal alloys known to those of ordinary skill in the art, such as lead, solder, copper, silver, aluminum, gold, etc. In various embodiments, the pads 214 include power pads 214a and ground pads 214b.

Substrate 230 also includes a plurality of conductive pads 236 (pads 236a and 236b are shown) on its surface (e.g., upper surface). The pads can be of any suitable type, geometry, and composition. The pads 236 can be formed of any suitable material, including metals or metal alloys known to those of ordinary skill in the art, such as lead, solder, copper, silver, aluminum, gold, etc. In various embodiments, the pads 236 include power pads 236a and ground pads 236b.

Ceramic capacitor 220 includes an array of vertical metal plates 224 embedded in a ceramic material 222. In an exemplary embodiment, the ceramic material includes a high-K ceramic material. In various embodiments, the high-K ceramic material has a dielectric constant of greater than about 1000 to 3000. In another embodiment, the high-K ceramic material has a dielectric constant of greater than about 3000. For example, the high-K ceramic material can include barium titanate (BaTiO₃)-based material, a lead complex Perovskite-based material, a strontium titanate (SrTiO₃)-based material, or the like.

The vertical metal plates 224 are perpendicular to the die 210 and substrate 230 facing surfaces. The vertical metal plates 224 include any conductive material, and in some embodiments, the metal plates include nickel. The vertical metal plates 224 provide parallel electrical connections in the vertical direction. The ceramic capacitor 220 replaces interconnections in the die shadow area (i.e., the area directly underneath the die 210 and defined by the perimeter of the die 210) of the substrate 230.

The ceramic capacitor 220 is electrically and physically coupled to the die 210 and the substrate 230 through the pads 214 and 236 and vertical metal plates 224, rather than through interconnections as in traditional implementations. The pads 214 of die 210 are coupled to one or more vertical metal plates 224 of the ceramic capacitor 220, and the pads 236 of the substrate 230 are coupled to one or more vertical metal plates 224 of the substrate 230. The protruding ends of the vertical metal plates 224 are coupled (e.g., soldered) to the pads 214 and pads 236 in the die 210 and substrate 230 sides. Die 210 is thus electrically coupled to substrate 230 through pads 214 of die 210, vertical metal plates 224 of ceramic capacitor 220, and pads 236 of substrate 230. The pads 214 and 236 and the vertical metal plates 224 are a means for coupling the die 210 to the substrate 230. In some embodiments, the vertical metal plates 224 are directly connected to internal Voltage Drain Drain (Vdd) and Voltage Source Source (Vss) nets in high power digital cores, thereby delivering an effective power distribution network (PDN) decoupling solution.

Because the ceramic capacitor 220 is very close to the die 210, the ceramic capacitor 220 can achieve very small parasitic inductance. The effectiveness of the ceramic capacitor 220 increases the closer it is to the die 210. The close location of the ceramic capacitor 220 to the die 210 allows current to be provided with a shorter response time than capacitors that are located farther from the die 210. In one example, low inductance (about 10 picohenries) and low resistance (about 10 milliohms) per core on a die can be achieved since many of the pads 214 and 236 act as a multitude of positive/negative terminals.

Due to the absence of interconnections between the die 210 and the ceramic capacitor 220, the ceramic capacitor 220 also has a lower inductance. The interconnections provide inherent and unwanted inductance.

To provide typical interconnections, careful and accurate alignment between pads and, for example, solder bumps must be made. In contrast, the ceramic capacitor 220 allows for generous alignment tolerances because electrical connections are made between the pads 214 and 236 with the plurality of vertical metal plates 224. Because there are several vertical metal plates 224 that are available to provide connections, each pad is not limited to connecting with a specific vertical metal plate. Instead, each pad is allowed to couple to any of a plurality of vertical metal plates 224.

In addition, a single ceramic capacitor 220, rather than numerous discrete capacitors, provides a PDN decoupling solution for multiple core digital domains in the capacitor shadow area (i.e., the area directly underneath the ceramic capacitor 220 and defined by the perimeter of the capacitor 220). Use of a single capacitor allows the manufacturing process to be simpler, faster, and more efficient.

Moreover, the ceramic capacitor 220 can be thin (e.g., about 100 μm thick). The ceramic capacitor 220 can fit into thin/small package substrates like integrated fan-out (INFO) substrates where neither an EPS capacitor nor SMT capacitor is applicable.

FIG. 2C provides a top view of the ceramic capacitor 220 in FIG. 2B. As shown, the vertical metal plates 224 are staggered, i.e., alternating or zigzag, not arranged consecutively in a straight line. This arrangement can maximize capacitance. By such an arrangement, the effective surface areas of positive vertical metal plates and negative vertical plates facing each other can be increased, while preventing pads of different polarities from shorting. The circles 226 indicate groups of vertical metal plates 224 that are coupled to pads 214 and/or pads 236. For example, circle 226a encompasses metal plates that are coupled to power pads 214a and/or 236a, and circle 226b encompasses metal plates that are coupled to ground pads 214b and/or 236b.

### Example Methods of Manufacture

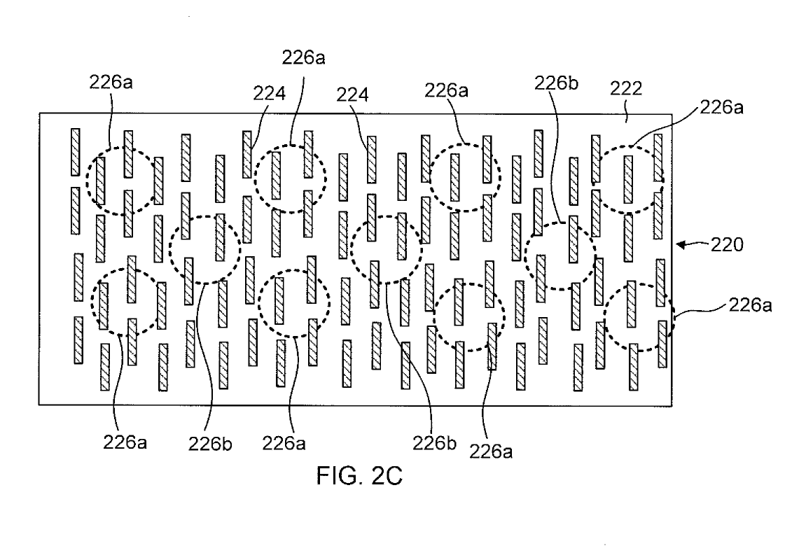

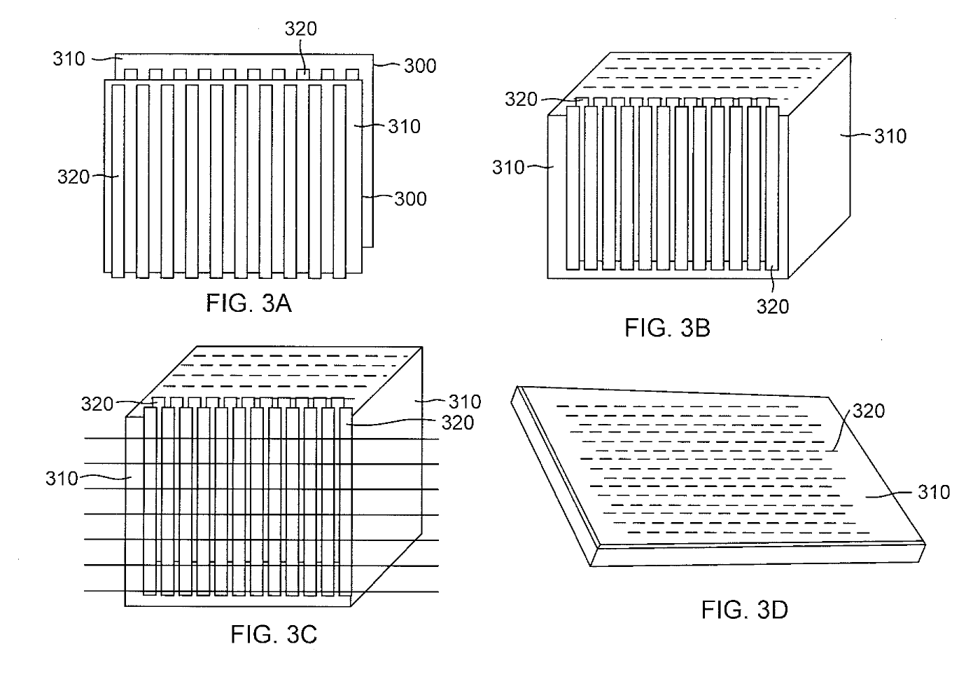

FIG. 3A through FIG. 3D illustrate manufacturing steps for forming a ceramic capacitor with vertical metal plates and reduced inductance, such as the ceramic capacitor 220 of FIGS. 2A-2C.

The process of making a ceramic capacitor is generally known and involves many steps. First, in a mixing step, a ceramic powder is mixed with binder and solvents to create a slurry. Next in a tape casting step, the slurry is poured onto a conveyor belt inside a drying oven, resulting in dry ceramic tape. The tape is then cut into green ceramic sheets.

In a screen printing step, electrode ink is made from a metal powder that is mixed with solvents and a ceramic material. The electrodes are printed onto the green ceramic sheets using a screen printing process.

Referring now to FIG. 3A, the sheets 300 are shown to include the ceramic 310 and the electrode ink 320. In FIG. 3B, in a stacking step, the sheets 300 are stacked to create a multilayer structure. In an embodiment, the sheets 300 are stacked so that the electrode ink 320 is staggered in adjacent sheets. That is, the electrode ink 320 on one sheet is not placed directly over the electrode ink 320 of an adjacent sheet. Instead, the sheets 300 are positioned so that the electrode ink 320 of one sheet 300 is in between the electrode ink 320 of a second sheet. This staggering or alternating arrangement can be seen in FIGS. 3A and 3B. This staggering arrangement maximizes capacitance. The sheets 300 are stacked until they reach the desired size. Pressure is then applied to the stack to fuse all the separate layers.

In FIG. 3C, the fused stack is cut into separate capacitors. As shown, the capacitors are formed by cutting the stack horizontally, rather than vertically as in traditional implementations. Cutting the fused stack horizontally results in the formation of the vertical metal plates. In some embodiments, the fused stack is cut so that the resulting capacitors are about 100 gm thick. The capacitors are then fired in kilns with slow moving conveyor belts.

Next, a termination step provides the first layer of electrical and mechanical connection to the capacitor. Metal powder is mixed with solvents and glass fit to create the termination ink. Each terminal of the capacitor is then dipped in the ink and the parts are fired in kilns.

Using an electroplating process, the termination is plated with a layer of, for example, nickel and then a layer of, for example, tin. The nickel is a barrier layer between the termination and the tin plating. The tin is used to prevent the nickel from oxidizing. The final structure of the ceramic capacitor, including the vertical metal plates 320, is shown in FIG. 3D.

The protruding ends of the vertical metal plates 320 are then coupled (e.g., soldered) to pads on a die and substrate. The ceramic capacitors can then be tested.

### Method of Manufacturing Flowchart

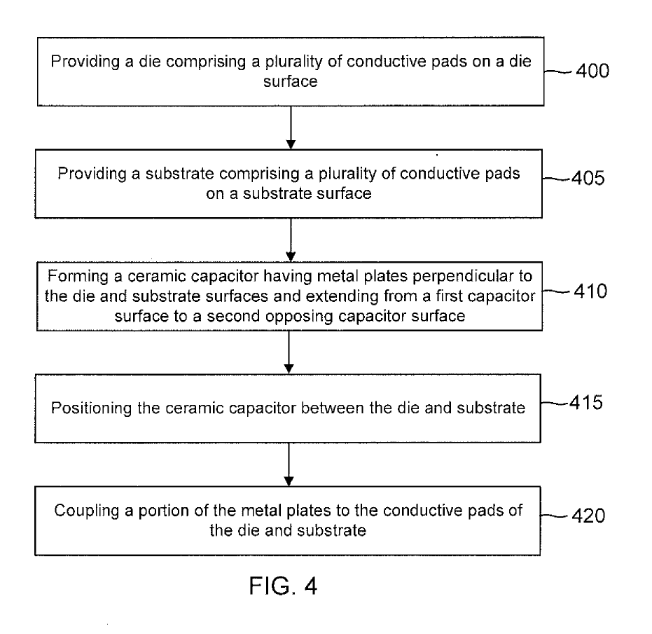

A manufacturing process generic to the various embodiments discussed herein may be summarized as shown in a flowchart of FIG. 4. A first step 400 comprises providing a die that includes a plurality of conductive pads on a die surface. This step is illustrated, for example, in FIG. 2B. A second step 405 comprises providing a substrate that includes a plurality of conductive pads on a substrate surface. An example of this step is shown in FIG. 2B. Next, the process includes a step 410 of forming a ceramic capacitor having metal plates perpendicular to the die and substrate surfaces and extending from a first capacitor surface to a second opposing capacitor surface. This step is illustrated, for example, in FIGS. 3A-3D.

In a next step 415, the ceramic capacitor is positioned between the die and substrate. The positioning of the ceramic capacitor between the die and substrate prevents warping of the resulting device caused by the warping of the substrate due to thermal changes. For example, the ceramic capacitor can help to counteract substrate shrinkage and/or expansion.

Finally, in step 420, the ends of the metal plates of the ceramic capacitor are coupled to the conductive pads on the die and substrate. In one embodiment, the metal plates are soldered to the pads. This step is illustrated, for example, in FIG. 2B.

The ceramic capacitor is electrically and physically coupled to the die and the substrate through the conductive pads on the die and substrate, rather than through interconnections as in traditional implementations. The pads of the die are coupled to one or more metal plates of the ceramic capacitor, and the pads of the substrate are coupled to one or more metal plates of the capacitor. The metal plates are perpendicular to die and substrate surfaces, as well as the first and second capacitor surfaces.

The ceramic capacitor and the semiconductor device formed from the ceramic capacitor have numerous advantages. The ceramic capacitor is very close to the die, which results in decreased parasitic inductance. The close location of the ceramic capacitor to the die allows current to be provided with a shorter response time than capacitors that are located farther from the die. There are no interconnections that provide inherent and unwanted inductance between the die and the capacitor, or between the capacitor and the substrate. Greater alignment tolerances are provided by the plurality of metal plates. The ceramic capacitor is thin, allowing it to fit in thin and small substrates where traditional capacitors cannot fit or are not suitable.

### Example Electronic Systems

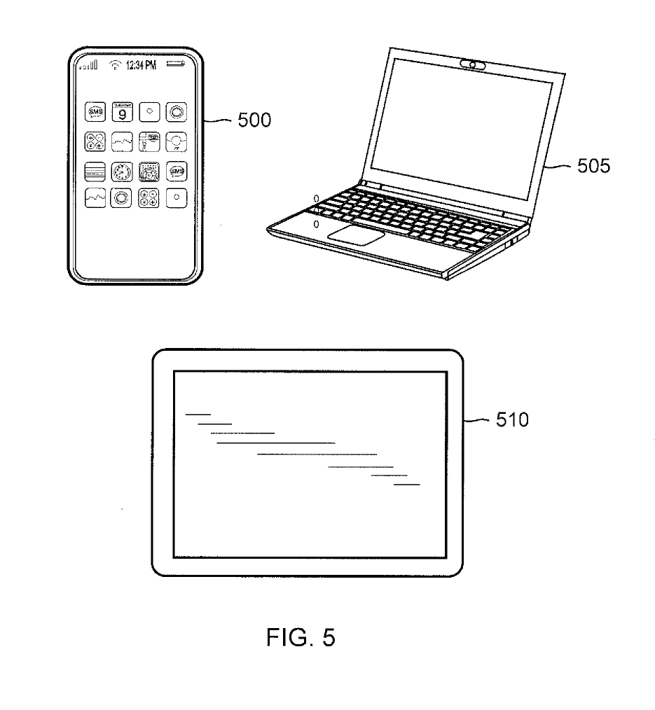

Semiconductor devices including a ceramic capacitor as disclosed herein may be incorporated into a wide variety of electronic systems. For example, as shown in FIG. 5, a cell phone 500, a laptop 505, and a tablet PC 510 may all include a semiconductor device incorporating a ceramic capacitor constructed in accordance with the present disclosure. Other exemplary electronic systems such as a music player, a video player, a communication device, and a personal computer may also be configured with semiconductor devices constructed in accordance with the disclosure.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

We claim:

1. A ceramic capacitor, comprising:
a first capacitor surface;
a second opposing capacitor surface; and
metal plates perpendicular to the first capacitor surface and second opposing capacitor surface and extending from the first capacitor surface to the second opposing capacitor surface,
wherein the ceramic capacitor is capable of being interposed between a die and a substrate, and
wherein a portion of the metal plates are capable of being coupled to conductive pads of the die on the first capacitor surface and to conductive pads of the substrate on the second capacitor surface.

2. The ceramic capacitor of claim 1, wherein the substrate comprises a package substrate or a die substrate.

3. The ceramic capacitor of claim 1, wherein the ceramic capacitor comprises a high-K ceramic material.

4. The ceramic capacitor of claim 3, wherein the high-K ceramic material comprises a ceramic material having a dielectric constant greater than 3000.

5. The ceramic capacitor of claim 1, wherein the metal plates comprise nickel.

6. The ceramic capacitor of claim 1, wherein the metal plates are staggered to each other.

7. The ceramic capacitor of claim 1, wherein the ceramic capacitor has a thickness of about 100 μm.

8. The ceramic capacitor of claim 1, wherein the metal plates are capable of being soldered to the pads of the die and the pads of the substrate.

9. The ceramic capacitor of claim 1, wherein the pads of the die and the pads of the substrate comprise power pads and/or ground pads.

10. The ceramic capacitor of claim 1, wherein the ceramic capacitor is incorporated into at least one of a cellphone, a laptop, a tablet, a music player, a communication device, a computer, and a video player.

11. A method comprising:
providing a die comprising a plurality of conductive pads on a die surface;
providing a substrate comprising a plurality of conductive pads on a substrate surface;
forming a ceramic capacitor having metal plates perpendicular to the die and substrate surfaces and extending from a first capacitor surface to a second opposing capacitor surface;
positioning the ceramic capacitor between the die and substrate; and
coupling a portion of the metal plates to the conductive pads of the die and substrate.

12. The method of claim 11, wherein forming the ceramic capacitor comprises stacking sheets comprising an electrode ink printed onto a ceramic sheet into a multilayer structure.

13. The method of claim 12, wherein forming the ceramic capacitor further comprises staggering the electrode ink in adjacent sheets.

14. The method of claim 12, wherein forming the ceramic capacitor further comprises slicing the multilayer structure into capacitors having a 100 μm thickness.

15. The method of claim 11, wherein positioning the ceramic capacitor comprises positioning the ceramic capacitor substantially directly underneath the die in the direction of the substrate.

16. The method of claim 11, wherein coupling a portion of the metal plates comprises soldering a portion of the metal plates to the pads of the die and substrate.

17. A device, comprising:
a die;
a substrate;
a ceramic capacitor interposed between the die and the substrate; and
means for coupling the capacitor to the die and the substrate.

18. The device of claim 17, wherein the means comprise a plurality of conductive pads on a die surface, a plurality of conductive pads on a substrate surface, and metal plates perpendicular to the die and substrate surfaces and extending from a first capacitor surface to a second opposing capacitor surface.

19. The device of claim 18, wherein a portion of the metal plates are coupled to the pads of the die on the first capacitor surface and to the pads of the substrate on the second opposing capacitor surface.

20. The device of claim 19, wherein the portion of the metal plates are soldered to the pads of the die and the pads of the substrate.
